(19) United States
(12) Patent Application Publication
(10) Pub. No.: US 2025/0238576 A1
(43) Pub. Date: Jul. 24, 2025

(54) AUTOMATED SYSTEM DESIGN DEVICE, AUTOMATED SYSTEM DESIGN METHOD, AND NON-TRANSITORY STORAGE MEDIUM

(71) Applicant: NEC Corporation, Tokyo (JP)

(72) Inventors: Toshiki WATANABE, Tokyo (JP); Takayuki KURODA, Tokyo (JP); Satoshi AKABORI, Tokyo (JP)

(73) Assignee: NEC Corporation, Tokyo (JP)

(21) Appl. No.: 19/033,619

(22) Filed: Jan. 22, 2025

(30) Foreign Application Priority Data
Jan. 24, 2024 (JP) 2024-008547

(51) Int. Cl. G06F 30/20

(52) U.S. Cl. CPC G06F 30/20

(57) ABSTRACT

An automated system design device includes: a means for accepting a system requirement; and a means for deriving a concrete system configuration by applying a predefined concretization pattern for each configuration element based on the system requirement, wherein the means for deriving a system configuration in a case where the multi-element is a single configuration element that represents a plurality of configuration elements of a same type, in concretizing the multi-element, advances the concretization of the multi-element without decomposing it into individual configuration elements to thereby design a redundant system configuration.

This application is based upon and claims the benefit of priority from Japanese patent application No. 2024-008547, filed Jan. 24, 2024, the disclose of which is incorporated herein in its entirety by reference.

### TECHNICAL FIELD

The present disclosure relates to an automated system design device, an automated system design method, and a non-transitory storage medium.

### BACKGROUND ART

As IT (Information Technology) and DX (Digital Transformation) become more widespread, constructed systems are becoming increasingly diverse and large-scale. Since manually designing, constructing, and managing these systems is extremely difficult, autonomous operation techniques that can autonomously perform the series of processes of system design, construction, and operational management are gaining attention. One of the key techniques within this field is the automated system design technique, which automatically designs system configurations that meet a wide variety of user (designer) requirements. In the automated system design technique, concrete system configurations that meet abstract user requirements, referred to as “Intents”, are derived based on such requirements. The types of system requirements that users can specify are varied, but among these, availability requirements are of significant importance. Availability requirements refer to conditions required for the continuous operation of a system, making it essential to automatically design redundant system configurations to ensure the system remains operational, even in the event of partial failures.

In the system configuration automated design technique disclosed in Patent Document 1 (PCT International Publication No. WO 2019/216082) and Non-Patent Document 1 (Takuya KUWAHARA, Takayuki KURODA, Takao OSAKI, Kozo SATODA, “An Intent-Based System Configuration Design for IT/NW Services with Functional and Quantitative Constraints”, IEICE Transactions on Communications Vol. E104-B, No. 7, pp. 791-804, 2021), a concrete system configuration that meets the functional and non-functional requirements required by a user is automatically designed.

The technique disclosed in these documents defines, in advance, information that expresses the method of concretizing each configuration element of the system (hereinafter referred to as concretization pattern) for each system configuration element, and generates various system configuration plans by combining any of these concretization patterns. It also enables the automated design of a system by searching for an appropriate configuration among the generated plans. In addition to the concretization patterns, by defining the conditions that each system configuration element or its surrounding configuration elements to be satisfied, configuration plans that do not meet these conditions are immediately rejected, and this limits the search range, thereby enhancing the efficiency of the design process.

However, the content presented in these documents describes a framework for automatically designing system configurations that meet various system requirements, but does not provide specific information about concretization patterns or other details for automatically designing systems with particular configurations. As a result, the content presented in these documents alone makes it difficult to design a redundant system configuration.

Furthermore, Patent Document 2 (Japanese Unexamined Patent Application Publication No. 2021-136692) realizes automated design by using a different approach than the one used in the aforementioned documents. In this document, the design of a physical configuration is performed by selecting physical devices to satisfy user-input communication requirements in an environment where redundant network paths already exist but the network devices to mediate those paths have not yet been determined. In this process, the design time is reduced by treating redundant paths and devices as a single unified element, however, this method does not design the redundant configuration itself.

### SUMMARY

An example of an object of the present disclosure is to provide an automated system design device, an automated system design method, and a non-transitory storage medium for realizing automated design of redundant configurations in a short period of time.

According to an example aspect of the present disclosure, an automated system design device includes: a means for accepting a system requirement; and a means for deriving a concrete system configuration by applying a predefined concretization pattern for each configuration element based on the system requirement, wherein the means for deriving a system configuration has a function to design a redundant configuration from a multi-element including an unspecified number of, or two or more of the configuration elements in a case where the multi-element is a single configuration element that represents a plurality of configuration elements of a same type, and in concretizing the multi-element, advances the concretization of the multi-element without decomposing it into individual configuration elements to thereby design a redundant system configuration.

According to an example aspect of the present disclosure, an automated system design method includes: accepting a system requirement; and deriving a concrete system configuration by applying a predefined concretization pattern for each configuration element based on the system requirement, wherein in the deriving, in a case where the multi-element is a single configuration element that represents a plurality of configuration elements of a same type, the concretization of the multi-element is advanced without decomposing it into individual configuration elements to derive the redundant configuration from the multi-element including an unspecified number of, or two or more of the configuration elements.

According to an example aspect of the present disclosure, a non-transitory storage medium that stores a program causes a computer to execute processes, the processes includes: accepting a system requirement; and deriving a concrete system configuration by applying a predefined concretization pattern for each configuration element based on the system requirement, wherein in the deriving, in a case where the multi-element is a single configuration element that represents a plurality of configuration elements of a same type, the concretization of the multi-element is advanced without decomposing it into individual configuration elements to derive the redundant configuration from the multi-element including an unspecified number of, or two or more of the configuration elements.

### BRIEF DESCRIPTION OF THE DRAWINGS

FIG. 1 is a block diagram showing a configuration example of an automated system design device.

FIG. 2 is a diagram showing an example of a representation of system configuration information.

FIG. 3 is a diagram showing an example of a textual representation of system configuration information.

FIG. 4 is a diagram showing an example of a definition format of a configuration element.

FIG. 5 is a diagram showing an example of definitions of configuration components.

FIG. 6 is a diagram showing an example of definitions of relationships between configuration components.

FIG. 7A is a first diagram showing an example of system configuration concretization.

FIG. 7B is a second diagram showing an example of system configuration concretization.

FIG. 8 is a diagram showing an example of a process for making a multi-element redundant and concretizing it.

FIG. 9 is a diagram showing an example of textual representations of expected surrounding configurations that can be applied to a multi-element.

FIG. 10 is a diagram showing an example of concretization in cases where decomposition of a multi-element is prioritized and where expansion is prioritized.

FIG. 11 is a diagram showing an example of the flow of a process for expanding a multi-element specified with an absolute number.

FIG. 12 is a diagram showing an example of the flow of a process for expanding a multi-element specified with a relative number.

FIG. 13 is a diagram showing an example of a textual representation of system configuration information including expansion dependencies.

FIG. 14 is a diagram showing an example of the flow of a process for decomposing a multi-element specified by absolute numbers.

FIG. 15 is a diagram showing an example of the flow of a process for decomposing a multi-element specified by relative numbers.

FIG. 16 is a diagram showing an example of a system configuration designed based on differences in the timing of decomposition of multi-elements.

FIG. 17 is a flowchart showing an example of an operation of the automated system design device.

FIG. 18 is a flowchart showing an example of details of a process for extracting a system configuration that can be generated in a one-stage concretization process.

FIG. 19 is a flowchart showing an example of details of an expansion process and a decomposition process of a multi-element.

FIG. 20 is a second block diagram showing a configuration example of the automated system design device.

FIG. 21 is a second flowchart showing an example of an operation of the automated system design device.

FIG. 22 is a diagram showing a hardware configuration example of the automated system design device.

### EXAMPLE EMBODIMENTS

Hereinafter, an automated system design device according to each example embodiment of the present disclosure will be described, with reference to the drawings. In the drawings used in the following description, the configuration of portions unrelated to the present disclosure may be omitted and may not be illustrated. In all drawings, the same or corresponding elements are denoted by the same reference signs, and common descriptions may be omitted.

### First Example Embodiment

### [Description of Configuration]

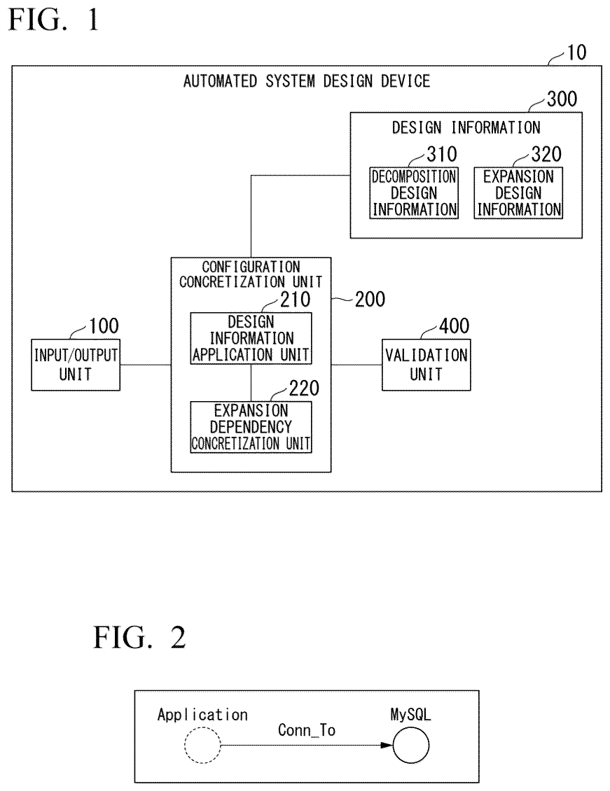

An automated system design device according to an example embodiment of the present disclosure will be described. FIG. 1 is a block diagram showing a configuration of the automated system design device.

As shown in FIG. 1, an automated system design device 10 includes an input/output unit 100, a configuration concretization unit 200, design information 300, and a validation unit 400.

The input/output unit 100 shown in FIG. 1 accepts system requirements, including the expected configuration, functionality, and performance of a system, as input and has a function of passing them to the configuration concretization unit 200. Furthermore, it has a function of receiving system configuration information that satisfies the system requirements from the configuration concretization unit 200 and outputting the system configuration information. If system configuration information satisfying the system requirements is not received from the configuration concretization unit 200, information indicating the failure to design a system configuration that satisfies the system requirements is output. The configuration concretization unit 200 receives the system requirements from the input/output unit 100, and derives a concrete system configuration based on the received system requirements. Specifically, the configuration concretization unit 200 acquires design information applicable to the system requirements or the system configuration under designed from the design information 300, and applies it to the system requirements or the system configuration under design, thereby concretizing the system configuration in stages. Design information applicable to system requirements or system configuration refers to design information that is applicable to configuration elements included in the system requirements or system configuration that have not yet been fully concretized, and if multiple pieces of applicable design information are available, several can be acquired. The configuration concretization unit 200 further passes the system configuration information under design to the validation unit 400 and receives the validation results from the validation unit 400. The design information 300 is design information that defines attribute information of the configuration elements of the system and a method of concretization (concretization pattern). The validation unit 400 acquires from the configuration concretization unit 200 information on the system configuration under design and constraint conditions to be satisfied by the system configuration, and validates whether or not these constraint conditions are satisfied. Thereafter, the validation unit 400 returns the validation result to the configuration concretization unit 200. The timing at which the configuration concretization unit 200 sends the system configuration information and constraint conditions to the validation unit 400, that is, the timing at which the validation unit 400 validates the constraint conditions, can be arbitrarily specified. For example, validation may be performed each time a piece of design information is applied to the system configuration under design, or validation may be performed after a plurality of pieces of design information are applied.

As shown in FIG. 1, the configuration concretization unit 200 is composed of a design information application unit 210 and an expansion dependency concretization unit 220. The design information application unit 210 applies the design information acquired from the design information 300 to the system requirements or the system configuration under design, thereby concretizing the system configuration in one stage. The expansion dependency concretization unit 220 performs processing to concretize a multi-element when there are multiple elements to which design information is applied, ensuring that no contradictions exist in the system configuration. A multi-element is a configuration element in which multiple configuration elements of the same type are grouped together and expressed as a single element.

As shown in FIG. 1, the design information 300 includes decomposition design information 310 and expansion design information 320. The decomposition design information 310 refers to information that defines a concretization method specialized for a multi-element, taking into account the characteristics of the multi-element, and it defines the method for decomposing a configuration element, that is, a method for concretizing a multi-element by creating multiple individual configuration elements of the same type as the multi-element. The expansion design information 320 refers to information that defines a concretization method in which surrounding configuration elements required for the existence of the configuration element are generated, regardless of whether it is a multi-element.

### [Data Representation]

Next, the data handled by the automated system design device 10 will be described. The data handled by the automated system design device 10 are mainly system requirements and system configurations. System requirements refer to information regarding requirements that the user performing the system design expects from the system, and include information that defines the functional and non-functional requirements of the system to be designed. System configuration refers to the configuration information of the system under designed by the configuration concretization unit 200, or the configuration information of the system for which the concretization has been completed and finally output by the automated system design device 10.

System requirements and system configuration are represented using nodes and edges. A node represents a configuration component that constitutes a system, while an edge represents the relationship between configuration components. The configuration components and their relationships are collectively referred to as configuration elements. Hereinafter, when the term “relationship” is used, it refers to the relationship between configuration components. Any information that represents the characteristics of a configuration element can be set to the configuration element. Nodes and edges can also have conditions set as constraint conditions, either for themselves or for the surrounding configuration elements. FIG. 2 shows an example of a system configuration representation. The circles represent nodes, and the arrow connecting the circles represents an edge. The names attached to the nodes and edge indicate the type names of the configuration components and relationship, respectively. The dashed line represents an abstract configuration element, that is, a configuration element that has not yet been fully concretized, while the solid line represents a concrete configuration element. For example, FIG. 2 shows the system configuration information representing a scenario in which an application (Application) communicates with a concrete “MySQL” (registered trademark) database server (Conn_To).

Since “Application” represents an abstract node for an application, it is shown with a dashed line at this point. During the process of system configuration concretization, it will be concretized into a concrete application.

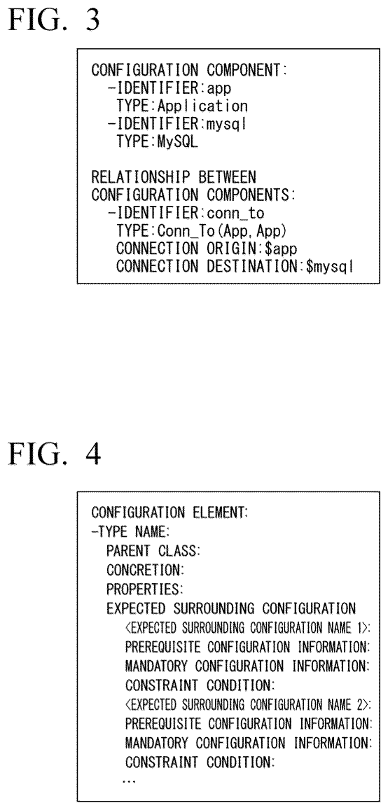

The configuration information shown in FIG. 2 can be represented not only by the diagram but also in text. The method of representation in text is not particularly limited, as long as it can be uniquely converted into a corresponding diagram. An example of a textual representation is shown in FIG. 3. The configuration information in text format includes a list of configuration components and the relationship between the configuration components. Each configuration component has at least an identifier for identifying the configuration component and the type of the configuration component defined, and, if necessary, property information for the configuration component is also defined. The relationship includes at least an identifier for identifying the relationship, the type of relationship, and the identifiers of the configuration components of connection origin and connection destination of the relationship are defined, and property information for the relationship is defined as needed. In FIG. 3, the symbol “$” indicates that the identifier for the variable name is referenced. If it is not necessary to define an identifier for a configuration element because the identifier is not referenced in other definitions of the configuration element, the definition of the identifier may be omitted.

### [Configuration Element Definition]

Next, a method for defining configuration elements will be described. The format for defining configuration elements is shown in FIG. 4. A configuration element can specify information that defines the characteristics of the configuration element, such as its type name, parent class, concretion, and properties, and also the configuration information it expects from its surroundings. Hereafter, the configuration information expected from its surroundings will be referred to as the “expected surrounding configuration”. The type name is the name of the configuration element type. The parent class indicates the type of another configuration element that the configuration element inherits, and if no specification is made, it indicates that nothing is inherited. A configuration element inherits the properties and expected surrounding configuration information of the parent class type by inheriting the type from another configuration element. Concretion refers to information that indicates whether the configuration element itself is an abstract configuration element that can be further concretized, or a concrete configuration element that cannot be further concretized. If the value is “true”, it represents a concrete configuration element, and if the value is “false”, it represents an abstract configuration element. A property refers to attribute information that represents the characteristics of a configuration element, and any attribute information can be specified according to the type of the configuration element.

The expected surrounding configuration refers to information of a configuration to be existed in the surroundings of a configuration element in order for that configuration element to be established, and the presence of the configuration described there indicates that the configuration element itself is established. For example, in order for an application to be present within a system, it requires to be installed on some operating system. Therefore, in the expected surrounding configuration of an Application-type configuration component, configuration information is defined indicating that the Application-type configuration component is hosted by some OS-type configuration component. Multiple types of expected surrounding configurations can be defined for one configuration element, and for each expected surrounding configuration, the name of the expected surrounding configuration, prerequisite configuration information, mandatory configuration information, and constraint conditions can be described. The prerequisite configuration information refers to the conditions for applying the expected surrounding configuration, and indicates that if the system configuration under design satisfies the configuration information described in the prerequisite configuration information, the mandatory configuration information described below is applied to concretize the system configuration. The mandatory configuration information represents the one-stage concretization of the system configuration by realizing the configuration information described here. The constraint conditions represent constraint conditions that each configuration element to be satisfied when applying this expected surrounding configuration.

Specifically, the process of concretizing a system configuration based on the input system requirements includes two processes: a process of concretizing the configuration elements themselves, included in the system requirements or the system configuration under designed, into concrete configuration elements; and a process of concretizing the system configuration by generating the required configuration elements to satisfy the expected surrounding configuration defined for each configuration element. The system design is considered complete when both of these processes are completed for all configuration elements in the system configuration. In other words, the system configuration design is considered complete if the concretion of all configuration elements within the system configuration is “true”, and the expected surrounding configuration for all configuration elements is satisfied. If multiple expected surrounding configurations are defined for a single configuration element, it is sufficient for any one of those expected surrounding configurations to be satisfied. Furthermore, in the case where concretizing the system to satisfy the expected surrounding configuration of a configuration element, if all or some of the configuration elements listed in the mandatory configuration information already exist within the system configuration, the system may be concretized into a configuration in which new configuration elements are generated, or the system may be concretized into a configuration in which existing configuration elements are reused without generating new configuration elements. For example, if the expected surrounding configuration of an Application-type configuration component defines configuration information such that it is hosted by some OS-type configuration component, a new OS may be added to the system configuration under designed to satisfy the expected surrounding configuration of this “Application”, or if there is already an OS in the system configuration where another “Application” is hosted, a configuration in which the “Application” is hosted by the existing OS may be realized without adding a new OS. Thus, when applying the expected surrounding configuration, it is optional to choose whether to concretize the configuration elements into a newly generated configuration or to concretize the configuration elements into a configuration that reuses existing configuration elements, and different system configurations are designed depending on the choice.

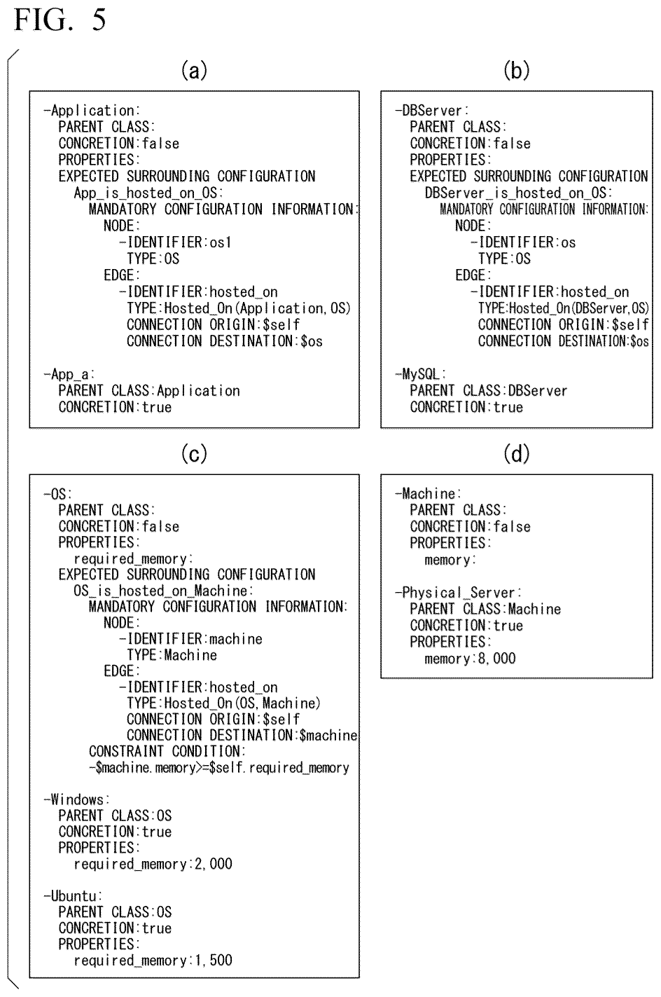

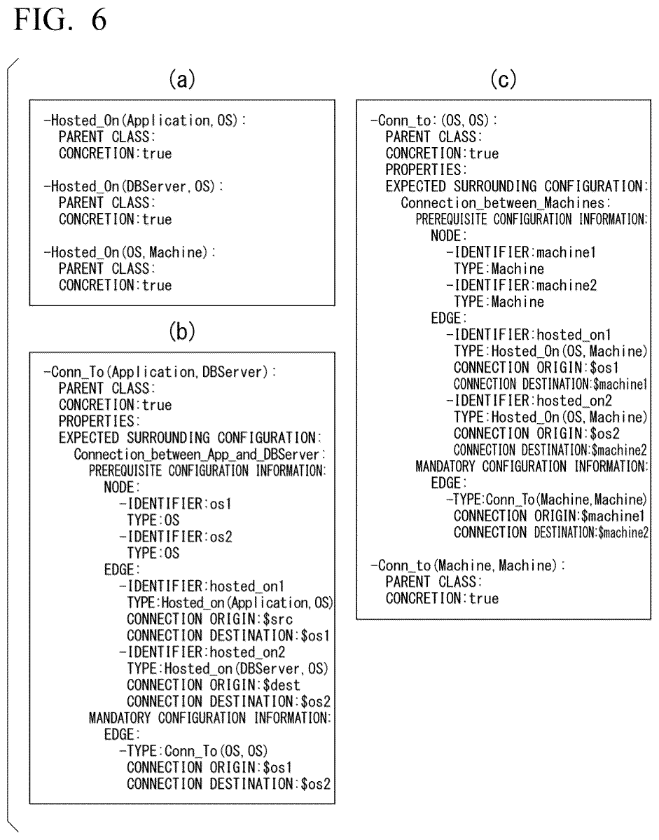

Below, examples of the definitions of configuration components and the relationships between configuration components will be provided. First, FIG. 5 shows examples of the definitions of the configuration components of an application, a database server, an OS, and a machine. The “Application” of FIG. 5 (a) is a configuration component that represents an application. The “Application” is an abstract configuration component of individual concrete application software, and is concretized into some concrete application. Therefore, its concretion is set to “false”. Furthermore, since “an application requires to be hosted on the OS in order to operate”, the corresponding configuration information is defined as the expected surrounding configuration “App_is_hosted_on_OS”. Specifically, this expected surrounding configuration defines that a partial configuration in which a “Hosted_On” relationship exists between the “Application” and the OS is concretized. The identifiers in the expected surrounding configuration are information for uniquely specifying configuration elements in the expected surrounding configuration. For example, in the case where multiple OS-type configuration elements appear within the expected surrounding configuration, it is required to clearly specify which OS-type configuration element is being referred to. In the case of “Conn_To (Application, DBServer)” of FIG. 6 described later, multiple OS-type configuration elements are defined in the expected surrounding configuration, and therefore, the identifications “os1” and “os2” are specified for each OS-type configuration element. In addition, in FIG. 5 (a), a configuration component called “App_a” is defined that inherits the “Application” and represents a concrete application. By inheriting the type “Application”, “App_a” inherits the properties and expected surrounding configuration defined in the Application type. Also, since “App_a” is a configuration component that represents a concrete application, such as some application product, the concretion is set to “true”.

The “DBServer” of FIG. 5 (b) is a configuration component that represents a database server. The “DBServer” is a configuration component that abstracts various concrete database server products and has concretion set to “false”. As with “Application”, “DBServer” is required to be hosted on some OS, as defined in the expected surrounding configuration “DBServer_is_hosted_on_OS”. Furthermore, it defines a configuration component called “MySQL” (registered trademark) that inherits from the “DBServer” and represents a specific DBServer product. The OS in FIG. 5 (c) is an abstract configuration component that represents an operating system and has a property, “required_memory” that represents the amount of memory used by the OS. However, since the OS-type configuration component is an abstract OS, no concrete value is set. Since the OS requires to be hosted on some “Machine” in order to operate, this is defined as an expected surrounding configuration called “OS_is_hosted_on_Machine”. Moreover, as a constraint condition for applying the expected surrounding configuration, it is defined such that the amount of memory installed in the host “Machine” is equal to or greater than the memory usage of the OS itself. In addition, configuration components of “Windows” (registered trademark) and Ubuntu type (“Ubuntu” is a registered trademark) which are concrete OSes are defined in a form of inheritance of the OS, the concretion is set to “true”, and a concrete value of memory usage is set. The “Machine” of FIG. 5 (d) is an abstract configuration component that represents the medium that hosts the OS and applications, and has a property called memory, which represents the amount of memory the “Machine” has. Furthermore, a configuration component of the Physical_Server type that represents a general physical server is defined by inheriting the “Machine”, and concretion is set to “true” while a concrete installed memory amount is specified.

Next, FIG. 6 shows examples of the definitions of the relationships between the configuration components defined in FIG. 5. The “Hosted_On” of FIG. 6 (a) is a relationship that represents a configuration component being hosted by another configuration component, and defines three relationships: “Hosted_On (Application, OS)”, which represents an “Application” being hosted on an OS; “Hosted_On (DBServer, OS)”, which represents a “DBServer” being hosted on an OS; and “Hosted_On (OS, Machine)”, which represents an OS being hosted on a “Machine”. The “Hosted_On” relationship is a concrete relationship, and is defined as having no properties or expected surrounding configurations.

The “Conn_To” is a relationship that indicates that two configuration components are logically or physically connected, and there are three defined: “Conn_To (Application, DBServer)”, which represents a connection between an “Application” and a “DBServer”; “Conn_To (OS, OS)”, which represents a connection between OSes; and “Conn_To (Machine, Machine)”, which represents a connection between “Machines”. The “Conn_To (Application, DBServer)” defines the expected surrounding configuration as one in which the “OSs” hosting the “Applications” and “DBServers” on both ends are connected to each other via “Conn_To”. This means that for an application and a database server to communicate, the “OSs” hosting them are required to be able to communicate with each other. The “Conn_To (OS, OS)” defines the expected surrounding configuration in which the “Machines” hosting the OSes on both ends are connected to each other via “Conn_To”.

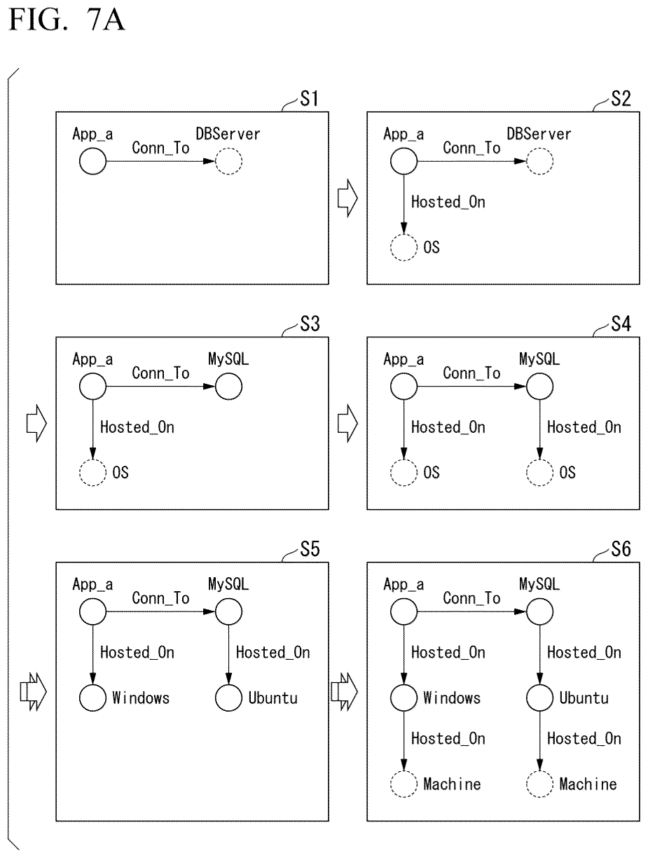

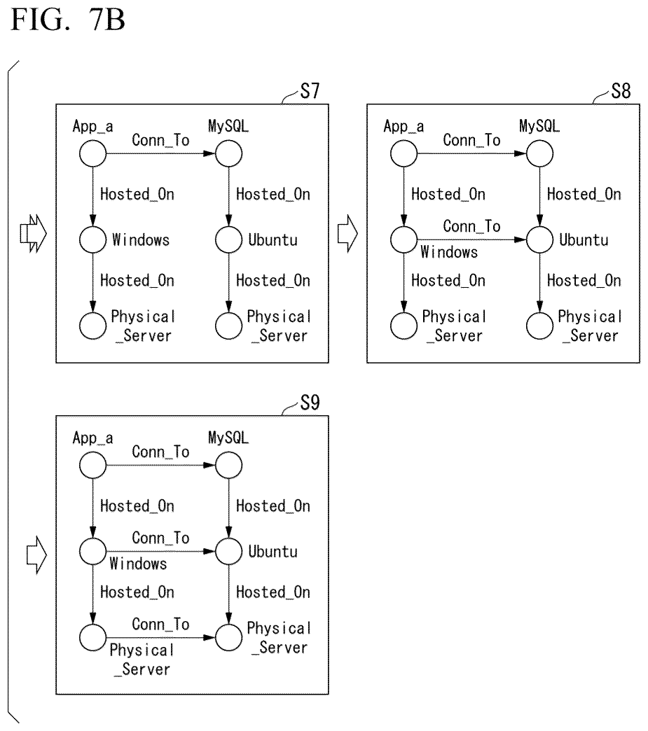

FIG. 7A and FIG. 7B show examples of system configurations using the configuration components and relationships between the configuration components defined in FIG. 5 and FIG. 6. The edge names in FIG. 7 omit the type names of the nodes at both ends. In FIG. 7A and FIG. 7B, assuming the system requirement of constructing a system where an application A, which uses a database, operates, the configuration in which the “App_a” and “DBServer” are connected via “Conn_To” is provided as input (S1 of FIG. 7A). At this point, since there are three configuration elements in the system configuration under design, the system configuration will be concretized by either concretizing the configuration elements themselves or advancing the concretization to satisfy the expected surrounding configuration of the configuration elements. Here, the “App_a” and “Conn_To (Application, DBServer)” have a concretion of “true”, and are not configuration elements that can be further concretized. Also, in order to apply the expected surrounding configuration of the “Conn_To (Application, DBServer)”, the “Application” and “DBServer” on both ends require each be hosted in the OS, so this cannot be applied at this point. For the above reasons, the types of concretization that can be applied at this point are: (1) concretizing the expected surrounding configuration of “App_a”; (2) concretizing the expected surrounding configuration of “DBServer”; and (3) concretizing “DBServer” itself. The description will proceed with the scenario (1) where concretization of the expected surrounding configuration of “App_a” is selected. The “App_a” generates an OS so as to satisfy its expected surrounding configuration, and concretizes it into a system configuration that has a “Hosted_On” relationship with the OS (S2 of FIG. 7A). Subsequently, the “DBServer” is concretized into “MySQL” (registered trademark) (S3 of FIG. 7A), and the relationship between the OS and “Hosted_On” is defined so as to satisfy the expected surrounding configuration of the “DBServer” (S4 of FIG. 7A). Then, each OS itself is concretized as “Windows” (registered trademark) or “Ubuntu” (registered trademark) (S5 of FIG. 7A), and a “Machine” is concretized in a form that satisfies the expected surrounding configuration of the OS (S6 of FIG. 7A). Furthermore, each “Machine” is concretized into a concrete “Physical_Server” (S7 of FIG. 7B). At this point, the prerequisite for applying the expected surrounding configuration of “Conn_To (Application, DBServer)”, namely, the configuration where “Application and DBServer are hosted on respective OSes” is satisfied. Therefore, to satisfy the expected surrounding configuration of the “Conn_To (Application, DBServer)”, “Conn_To (OS, OS)” is concretized between the OSes hosting the “Application” and “DBServer” (S8 of FIG. 7B). Finally, the “Conn_To (Machine, Machine)” is concretized between the “Machines” hosting each OS so as to satisfy the expected surrounding configuration of the “Conn_To (OS, OS)” (S9 of FIG. 7B). At this point, the concretion of all configuration components in the system configuration under designed is “true”, and all configuration components satisfy the expected surrounding configuration, and therefore, concretization of the system configuration is now complete.

Here, the concretization of the system configuration does not require to follow the specific order shown in FIG. 7A and FIG. 7B. If multiple concretization patterns are applicable to a given configuration element, any of them can be applied without issue. For example, it is acceptable not only to concretize the configuration from S1 to S2 as shown in FIG. 7A, but also to concretize the system configuration by first concretizing “DBServer” itself into a “MySQL” (registered trademark) starting from the configuration of S1. Moreover, if there are multiple applicable concretization patterns, the concretization pattern to be applied may be selected randomly or may be determined by other techniques such as machine learning.

### [Redundant Configuration Design]

The automated design method described so far is primarily based on the assumption that each configuration element is singular. In other words, a single node represents the existence of one configuration component, and a single edge represents the existence of one relationship, based on this assumption. On the other hand, in system design, there may be cases where multiple configuration elements require to be represented, or where there is a possibility of multiple configuration elements existing, but the exact number is undetermined. For example, in cases where a number of terminals, such as PCs, are present, multiple terminals may be represented as a single configuration component for the purpose of design. Alternatively, when considering performance and availability, it may be required to run multiple instances of the same application, but the exact number of instances to run may be unknown at the design stage. Thus, configuration elements that are multiple in number, or whose number is undetermined but may be multiple, are referred to as multi-element. If a “multi-element” is contained in the system requirements or the system configuration under design, the system configuration is required be concretized while considering the possibility that multiple configuration components may exist. However, the automated design method described so far does not include any special mechanism for simplifying the system configuration design, assuming the existence of multi-element components. In the following, the mechanisms and concretization patterns for advancing the concretization of a system configuration containing multi-element components without contradictions will be described.

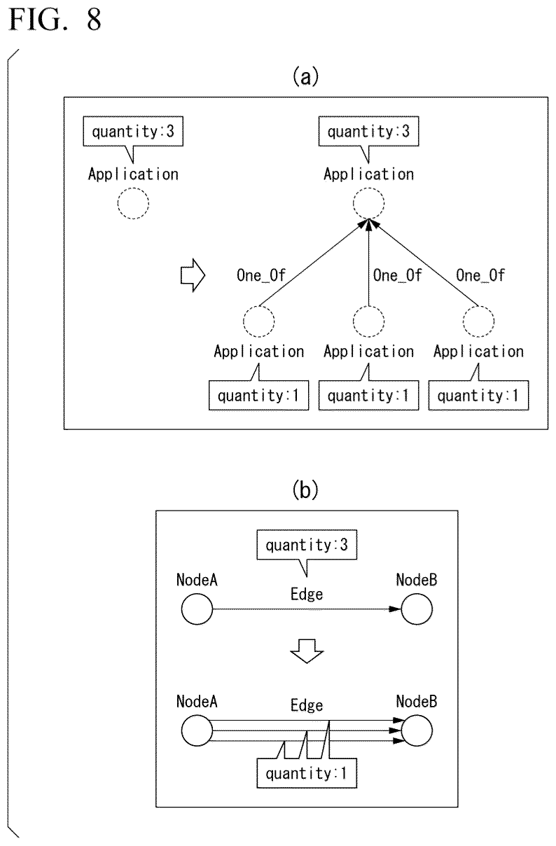

First, in order to handle multi-elements, the concept of number is introduced for each configuration element. Specifically, a “quantity” property that indicates the number of configuration elements is defined for each configuration element. Additionally, an expected surrounding configuration is defined that can only be applied to multi-elements, where the quantity is 2 or more, or where the number is undetermined but may potentially be 2 or more. The expected surrounding configuration, which is applied only to a multi-element, specifically refers to the concretization of a configuration element that is a multi-element, into a configuration that generates configuration elements of the same type, each with a quantity of 1, according to the value of the quantity. An example of an expected surrounding configuration, which can only be applied to a multi-element configuration component and relationships, is shown in FIG. 8. In FIG. 8 (a), the existence of three “Applications” is represented by one node, and “quantity=3” is set as a property of the node. As an expected surrounding configuration for this multi-element, it is concretized into a configuration that generates three nodes of the same “Application” type as this “Application” itself, each with “quantity=1”, based on the “quantity” value of the multi-element. Furthermore, in FIG. 8 (a), the relationship between the multi-element and the same type of configuration elements generated by concretizing the multi-element is connected by the relationship “One_Of”. In FIG. 8 (b), the existence of three edges between “NodeA” and “NodeB” is represented by one edge, and “quantity=3” is set as the edge property. As an expected surrounding configuration for this edge, it is concretized into a configuration that generates three edges of the same “Edge” type as this “Edge” itself, each with “quantity=1”, based on the “quantity” value of the multi-element.

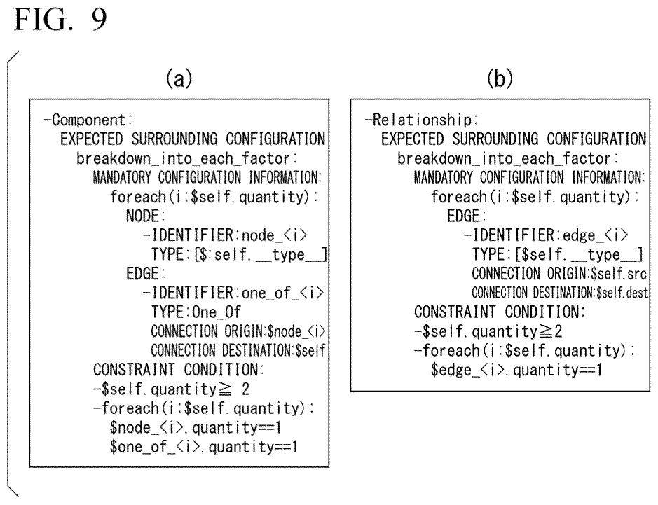

Examples of textual representations of expected surrounding configurations that can be applied to the multi-element configuration component and relationships are shown in FIG. 9 (a) and FIG. 9 (b), respectively. Here, the expected surrounding configuration that can be applied to the multi-element is not defined uniquely for each type of configuration element. Instead, the same expected surrounding configuration is defined for all multi-element configuration components and multi-element relationships. Therefore, instead of defining the expected surrounding configuration applicable to a multi-element for each individual configuration element, it is effective to define the expected surrounding configurations for both multi-element configuration components and multi-element relationships collectively, and have each configuration element inherit and reflect these configurations. In FIG. 9 (a), the “Component” type is defined as an expected surrounding configuration that can be applied to configuration components of a multi-element, and in FIG. 9 (b), the “Relationship” type is defined as an expected surrounding configuration that can be applied to the multi-element relationships. Each configuration element can have the information of the expected surrounding configuration corresponding to a multi-element by being defined in a way that inherits these types. In the following description, the process of concretizing the expected surrounding configuration specific to a multi-element, as shown in FIG. 8 and FIG. 9, by creating configuration elements of the same type according to the “quantity” value, will be referred to as “decomposition”.

Thus, by adding a quantity property to the configuration elements and advancing the concretization through decomposition based on the quantity, it becomes possible to design a redundant system configuration. However, with this method of concretization, the system configuration is concretized by prioritizing the decomposition of the multi-element. Since each configuration element generated through the decomposition is independently concretized, there is a problem of increased design time. For example, as shown in FIG. 8 (a), an “Application” with “quantity=3” is decomposed into three “Applications” with “quantity=1”, and then each “Application” is concretized independently. In other words, the OSes and “Machines” that the “Applications” require directly or indirectly are created. Therefore, a simple estimate is that the number of configuration elements in the system configuration will be three times as many as when an “Application” with “quantity=1” is concretized. In the automated design technique according to the present example embodiment, there are multiple expected surrounding configurations for each configuration element, and a system configuration that satisfies the requirements is searched for from among various system configurations that can be designed by combining these system configurations. Therefore, as the number of configuration elements in a system configuration increases, the number of possible design configuration plans also increases, and the system design time also increases.

Here, it is assumed that in redundant configurations, there are parts of the structure that are partially identical, and that it is not required to design each redundant system completely independently. For example, when designing a system configuration that redundantly deploys an application three times, in an on-premises environment, it may be desirable to standardize the configuration by preparing three physical servers of the same manufacturer and model, each with the same type and version of OS, “MW”, and application installed. Thus, for the common partial configuration, as shown in FIG. 8 (a), instead of immediately decomposing the multi-element and independently concretizing each decomposed configuration element, the concretization of the common partial configuration proceeds without decomposing the multi-element. Once the common part of the configuration is fully concretized, the multi-element is decomposed, allowing for a more efficient design process. In the following description, the concretization of a configuration element in configurations other than decomposition, that is, applying the expected surrounding configuration applicable to the configuration element regardless of the number of such configuration elements, will be referred to as “expansion”.

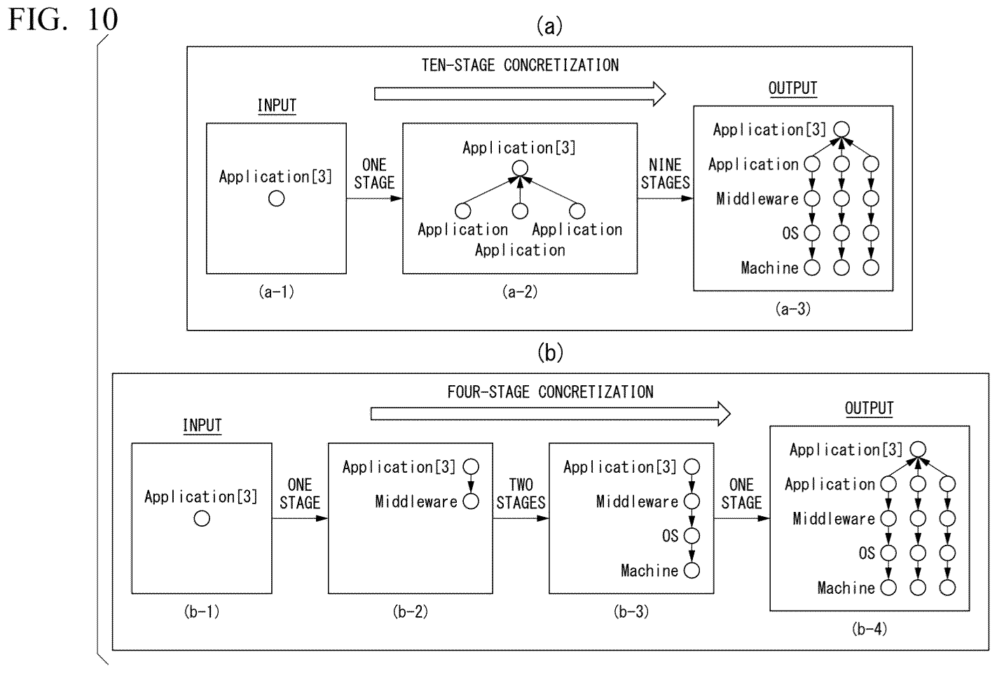

Examples of the concretization flow prioritizing the decomposition of a multi-element and the concretization flow prioritizing the expansion of a multi-element are shown in FIG. 10 (a) and FIG. 10 (b), respectively. In FIG. 10, the number enclosed in brackets “[ ]” following the name of a configuration element represents the “quantity” value of that configuration element, and the value is “quantity=1” where there is no brackets. When prioritizing the decomposition of a multi-element, an “Application” with “quantity=3” (a-1) is concretized into a configuration that includes three “Applications” with “quantity=1” through one-stage concretization (a-2). After that, the “Middleware” required by each “Application”, the OS required by the “Middleware”, and the “Machine” required by the OS are concretized in stages, and the concretization of the system of one “Application” is completed after three stages of concretization. To apply this to three “Applications”, a total of ten stages of concretization are required (a-3). On the other hand, when prioritizing deployment of the multi-element, an “Application” with “quantity=3” (b-1) is concretized by generating the “Middleware” required by the “Application” as an expected surrounding configuration (b-2) without decomposing it. After that, the design proceeds by concretizing the OS that the “Middleware” requires as an expected surrounding configuration, and the “Machine” that the OS requires as an expected surrounding configuration (b-3). Finally, the concrete system configuration is designed by decomposing the “Application” with “quantity=3” (b-4). In such a case, although the finally designed system configurations, as shown with (a-3) and (b-4), are the same, when prioritizing the decomposition of the multi-element, ten stages of concretization are required to complete the process. In contrast, when expanding while keeping the components as a multi-element, the concretization is completed in four stages.

Here, in the case of advancing the design by first expanding the multi-element and then decomposing it, simply decomposing and concretizing the multi-element itself, as shown in FIG. 8, is insufficient. Additionally, it is required to concretize the system configuration while maintaining the configuration components generated by the expansion of the multi-element, and the relationships with configuration elements having a relationship with the multi-element (that is, connected to the multi-element by some edge). Therefore, in the case of advancing the design by expanding the multi-element, the concretization is advanced while maintaining information about the configuration elements generated through the expansion of the multi-element and information about the number of the expansion origin multi-elements, as necessary. In the case of decomposing the multi-element, the decomposition is performed based on these pieces of information, while maintaining the required relationships in the system configuration. The following describes the method of expanding a multi-element and the method of decomposing it, for realizing an automated system design that allows multi-element expansion.

### [Multi-Element Expansion]

First, the method of expanding a multi-element will be described. In the case of expanding a multi-element without decomposing it, that is, in the case of concretizing in a way that satisfies the required expected surrounding configuration for the multi-element, two methods are anticipated for specifying the number of configuration elements generated through the expansion.

The first method is to specify the total number of configuration elements generated through the expansion, that is, to specify an absolute value indicating how many of these configuration elements exist in the system. For example, when designing a configuration where multiple VMs (Virtual Machines) operate on a single physical server, it is effective to specify the number (quantity) of configuration elements representing the physical server, generated by expanding the multi-element VM, as an absolute value, such as “1”.

The second method is to specify a relative value, that is, the number of configuration elements generated through the expansion for each of the expansion-origin multi-elements. For example, in the case of designing a configuration where multiple VMs operate on separate physical servers, the total number of physical servers depends on the number of expansion-origin VMs, making it difficult to specify a specific value in advance. Therefore, it is effective to advance the concretization by specifying a relative quantity, such as one physical server required for each expansion-origin VM, that is, the number of physical servers required for each expansion-origin multi-element. When proceeding with the expansion by specifying an absolute value and then decomposing the multi-element, it is required to concretize the system configuration while maintaining each of the decomposed configuration elements and the relationships between the configuration elements expanded from the decomposition-origin. On the other hand, when proceeding with the expansion by specifying a relative value and then decomposing the multi-element, it is required to concretize the system configuration by decomposing not only the decomposition target configuration element itself but also the configuration element that depends on the number of the decomposition target configuration elements.

The following will describe the processes for expansion by specifying an absolute value and for expansion by specifying a relative value.

### (In the Case of Specifying the Number of Expansion-Destination Configuration Elements, Using an Absolute Value)

First, the process for expanding a multi-element in the case where the number of expansion-destination configuration elements is specified by an absolute value will be described. The multi-element of expansion origin is concretized into a configuration that satisfies the expected surrounding configuration of the multi-element itself. Newly generated configuration elements generated through this concretization process, or those that have already been concretized in the system configuration and reused as part of the expected surrounding configuration for the multi-element, will set their total number as the “quantity” value. If the number is not clearly determined at this point, it may be specified as a variable. However, this value is determined independently of the number of expansion-origin multi-elements.

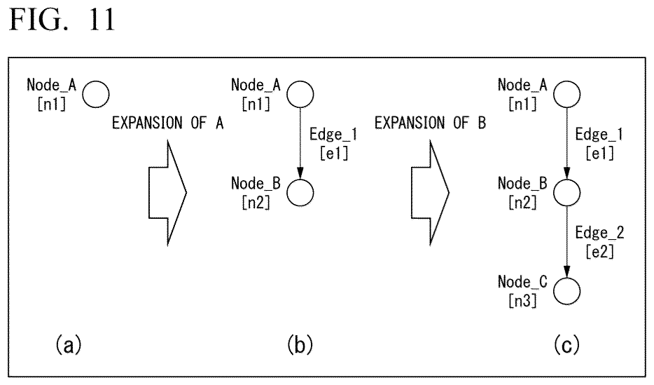

FIG. 11 shows the flow of the process of expanding a multi-element in the case where the number of expansion-destination configuration elements is specified as an absolute value. In FIG. 11, it is assumed that a “Node_A” has a “Node_B” and an “Edge_1” defined as its expected surrounding configurations, and the “Node_B” has a “Node_C” and an “Edge_2” defined as its expected surrounding configurations. The number enclosed in brackets “[ ]” following the name of a configuration element represents the “quantity” value of that configuration element. In other words, FIG. 11 shows how the “Node_A”, with a “quantity” of “n1”, is expanded while remaining as a multi-element. In the expansion of the “Node_A”, it is concretized by generating the “Edge_1” and “Node_B” so as to satisfy the expected surrounding configuration of the “Node_A” (FIG. 11 (b)). At this point, the generated “Node_B” and “Edge_1” retain their “quantity” values, representing the total number of themselves in the system, as variables “n2” and “e1”, respectively. Then, in the case of also expanding the “Node_B” while remaining as a multi-element, it is concretized by generating the “Edge_2” and “Node_C” so as to satisfy the expected surrounding configuration of the “Node_B”. In this case also, similarly, the generated “Node_C” and “Edge_2” retain their “quantity” values, representing the total number of themselves in the system, as variables “n3” and “e2”, respectively.

### (In the Case of Specifying the Number of Expansion-Destination Configuration Elements, Using a Relative Value)

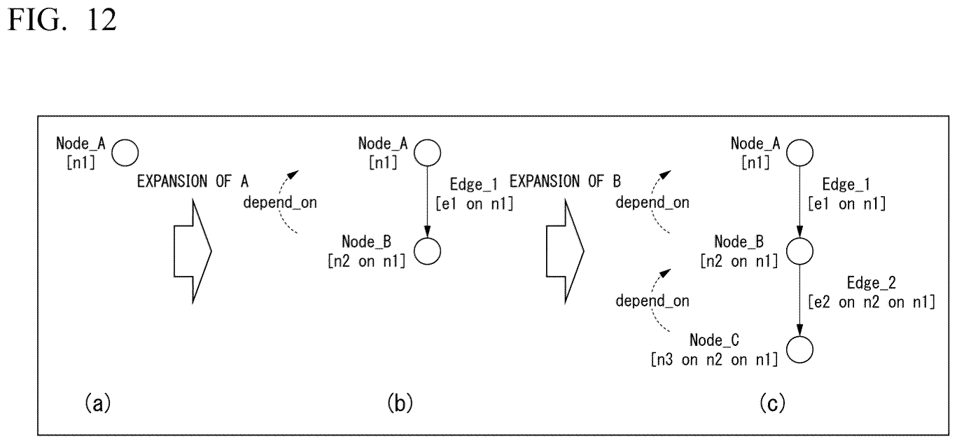

Subsequently, the process for expanding a multi-element in the case where the number of expansion-destination configuration elements is specified by a relative value will be described. The multi-element of expansion origin is concretized into a configuration that satisfies the expected surrounding configuration of the multi-element itself. During this configuration process, the generated configuration elements, or those that have already been concretized in the system and reused as part of the multi-element's expected surrounding configuration, retain information indicating that they were expanded from a multi-element. This includes the relationship that represents from which multi-element they were expanded (referred to as the “expansion dependency relationship”), the number of multi-elements themselves per one expansion-origin configuration element, and the total number of expansion-origin configuration elements. In the case where the expansion dependency relationship is multi-staged, meaning that elements generated by expanding a multi-element are themselves multi-elements, and additional configuration elements are generated by expanding these multi-elements, the finally generated configuration element retains, in addition to the number of the multi-elements themselves per one configuration element that are directly in the expansion dependency relationship and the number of configuration elements that are directly in the expansion dependency relationship, the number of configuration elements that are indirectly in the expansion dependency relationship. FIG. 12 shows the flow of the process of expanding a multi-element in the case where the number of expansion-destination configuration elements is specified as a relative value. First, a “Node_A” is concretized by generating an “Edge_1” and a “Node_B” in order to satisfy its expected surrounding configuration. In this case, the generated “Node_B” and “Edge_1” retain information indicating that they have an expansion dependency relationship with the “Node_A” (represented by the “depend_on” relationship, denoted as a dashed line in FIG. 12 (b)), as well as the values of “n2” or “e1”, which represent the number of the “Node_B” or “Edge_1” per one “Node_A” of the expansion origin, and the value of “n1”, which represents the total number of the “Node_A” of the expansion origin. At this point, the “quantity” value of the “Node_B” depends on “n2”, which is the number of the “Node_B” itself per one “Node_A” of the expansion origin, and “n1”, the “quantity” value of the Node_A. Therefore, the “Node_B” retains “n2 on n1” as the “quantity” value. This means that there are n1 instances of “Node_A”, and for each instance of “Node_A”, n2 instances of “Node_B” exist. Similarly, the “Edge_1” retains “e1 on n1” as the “quantity” value. Then, in the case of also expanding the “Node_B” while remaining as a multi-element, it is concretized by generating the “Edge_2” and “Node_C” so as to satisfy the expected surrounding configuration of the “Node_B”. The generated “Node_C” and “Edge_2” retain information indicating their expansion dependency relationship on the “Node_B”, along with the number of instances per one “Node_B” of the expansion origin, represented as “n3” or “e2”, the number of the “Node_B” instances, “n2”, and the number of the “Node_A” instances, “n1”, as the “Node_C” and “Edge_2” are indirectly in an expansion dependency relationship with the “Node_A”. In other words, the “Node_C” retains the “quantity” value as “n3 on n2 on n1”, and the “Edge_2” retains the “quantity” value as “e2 on n2 on n1” (FIG. 12 (c)).

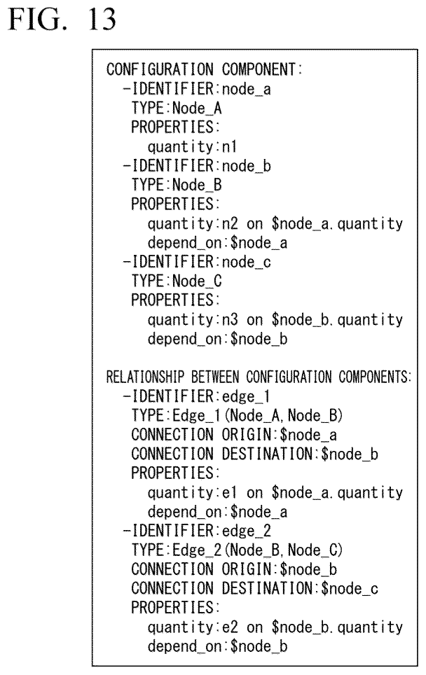

FIG. 13 shows an example of a textual representation of the system configuration information in the state shown in FIG. 12 (c). The representation example of FIG. 13 follows the description method of the system configuration information shown in FIG. 3, but adds the number of configuration elements and information imparted when a multi-element is expanded. Specifically, identifiers “node_a”, “node_b”, and “node_c” are set for the configuration components of type “Node_A”, “Node_B”, and “Node_C”, respectively, and a “quantity” property representing the number of each configuration element and a “depend_on” property representing the expansion dependency relationship are set. A “node_b” has an expansion dependency relationship with a “node_a” and retains the identifier of the expansion-dependency-destination “node_a” as the value for “depend_on”. Additionally, it retains the number of itself (n2) per one “node_a” of the expansion dependency destination and the number of “node_a” ($node_a.quantity) as the value of “quantity”. Similarly, a “node_C” retains the identifier of “node_b” of the expansion dependency destination as the value for “depend_on”, and retains the number of itself per one “node_b” (n3) and a value ($node_b.quantity) including the number of “node_b” per one “node_a” and the number of “node_a” as the value of “quantity”. Similarly, a “quantity” property and “depend_on” property are additionally defined for the relationships between configuration components. An “Edge_1” type relationship having an identifier “edge_1” set thereto, retains the identifier of the expansion dependency destination “node_a” as the value of “depend_on”, and retains the number of itself (e1) per one “node_a” and the number of “node_a” ($node_a.quantity) as the value of “quantity”. Similarly, an “edge_2” retains the identifier of “node_b” of the expansion dependency destination as the value for “depend_on”, and retains the number of itself per one “node_b” (e2) and a value ($node_b.quantity) including the number of “node_b” per one “node_a” and the number of “node_a” as the value of “quantity”.

When expanding a multi-element, the number of configuration elements generated through the expansion can be specified either as an absolute value or a relative value. If no specific method is specified, both configuration plans based on each specification method will be designed. Furthermore, within the same one system configuration, configuration elements specified with absolute values and those specified with relative values may coexist. For example, when expanding a certain multi-element, the number of generated configuration elements can be specified with a relative value, while the number of these newly generated configuration elements can be specified with an absolute value when they are expanded.

Additionally, depending on the type of configuration element, there may be cases where it is preferable to limit the concretization method to one of the two methods. In such a case, it may be considered to define information regarding which specification method to use for concretization within the definition of the configuration element type. For example, “dependency” may be defined as a configuration element type property, if a value is “True” a relative value is specified, and if a value is “False” an absolute value is specified.

### [Multi-Element Decomposition]

Next, the process for decomposing a multi-element will be described. The decomposition of a multi-element is performed in accordance with [Step 1] to [Step 6] shown below.

### [Step 1] Determination of Multi-Element to be Decomposed

First, the multi-element to be decomposed is selected from the system configuration under design. Decomposition of a multi-element can be applied to any multi-element within the system configuration. Hereafter, the multi-element selected for decomposition will be referred to as “decomposition-target element”

### [Step 2] Decomposition of Decomposition-Target Element Itself

The selected decomposition-target element itself is decomposed. Specifically, configuration elements of the same type as the decomposition-target element are created, with the number of created elements matching the quantity of the decomposition-target element, and the created configuration elements and the decomposition-target element are connected using a “One_Of” relationship. The quantity of each configuration element generated from the multi-element is set to 1. This is similar to the application of the concretization pattern shown in FIG. 8 (a).

[Step 3] Copying Relationships with Expansion Dependency Destination of Decomposition-Target Element

In the case where the decomposition-target element specifies another configuration element as the expansion dependency destination, the relationship between the expansion dependency destination and the decomposition-target element is copied to the decomposition destination element of the decomposition-target element. At this time, the expansion dependency relationship information is also copied. In other words, each configuration element generated by decomposition retains information about the relationship specifying the expansion dependency destination of the expansion dependency destination element of the decomposition-target element, and the value of the number of expansion dependency destinations (including indirect expansion dependency destinations).

[Step 4] Copying Configuration Elements with Direct and Indirect Expansion Dependencies on the Decomposition-Target Element

If configuration elements with direct and indirect expansion dependencies on the decomposition-target element are present within the system configuration, the partial configuration including those configuration elements is copied and connected to each configuration element generated through the decomposition of the decomposition-target element. Configuration elements with indirect expansion dependency on the decomposition-target element are those that can be traced indirectly through the expansion dependency relationship, such as configuration elements with expansion dependency on a configuration element having a direct expansion dependency on the decomposition-target element. The partial configuration including configuration elements with direct and indirect expansion dependencies on the decomposition-target element is copied, maintaining the relationships between those configuration elements and retaining the quantity and expansion dependency relationship information retained by each configuration element. This copied partial configuration is then connected to each configuration element generated through the decomposition of the decomposition-target element. However, the number of the decomposition-target elements, as retained by configuration elements with direct and indirect dependencies on the decomposition-target element, is updated to “1”. This is because the decomposition-target element has been divided into configuration elements, each with “quantity=1”, that are not multi-elements.

### [Step 5] Copying Other Surrounding Elements

If a relationship exists with the configuration elements of the decomposition origin in [Step 2] and configuration elements of the copy origin in [Step 4], that is, a relationship where the decomposition-origin configuration element in [Step 2] or copy-origin configuration element in [Step 4] function as either the connection origin or connection destination, then that relationship is also copied and connected to the decomposition destination configuration element in [Step 2] or the copy-destination configuration element in [Step 4].

### [Step 6] Removal of Unnecessary Elements

Configuration elements with direct and indirect expansion dependencies on the decomposition-target element, and relationships where these configuration elements serving as the connection origin or connection destination, are removed from the system configuration under designed.

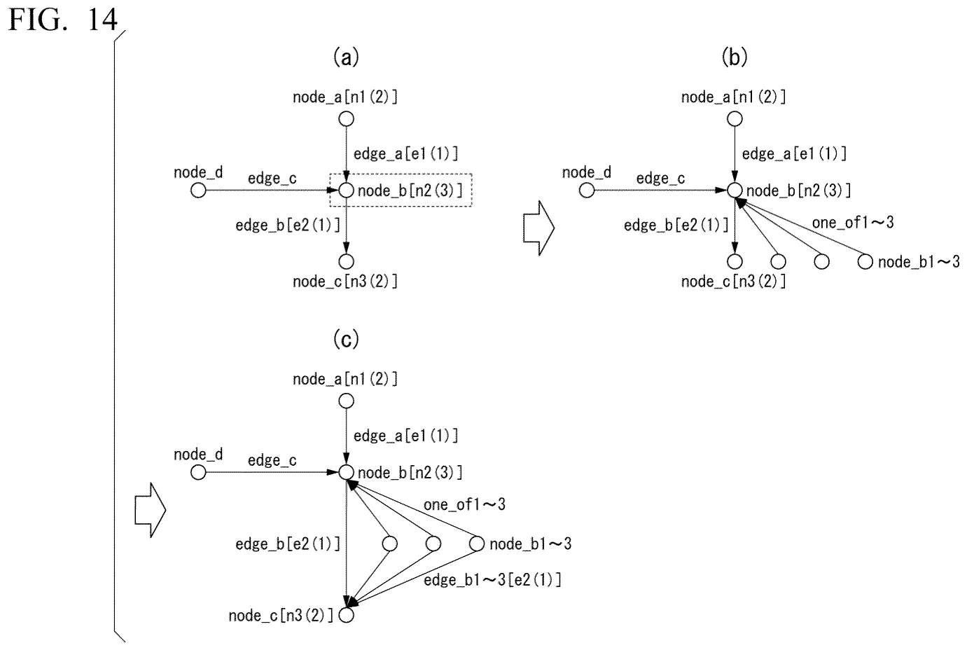

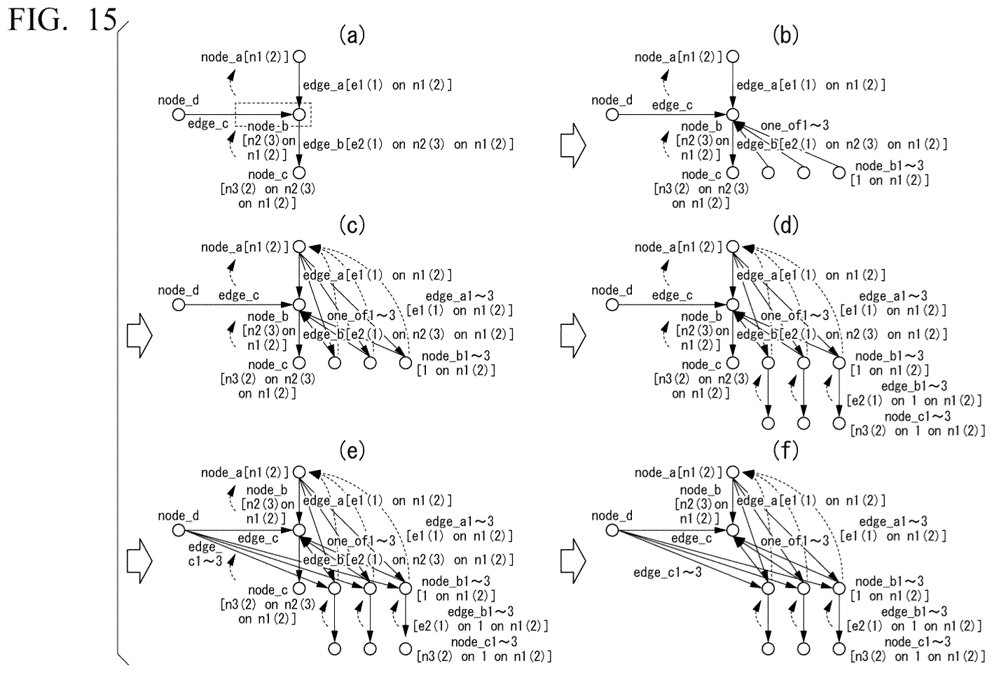

Specific examples of decomposition of multi-elements based on [Step 1] to [Step 6] described above are shown in FIG. 14 and FIG. 15. FIG. 14 shows the decomposition process when a multi-element is expanded, as shown in FIG. 11, and the number of expansion-destination configuration elements is specified as an absolute value. FIG. 15 shows the decomposition process when a multi-element is expanded, as shown in FIG. 12, and the number of expansion-destination configuration elements is specified as a relative value. In FIG. 14 and FIG. 15, the name of each configuration element is denoted using identifiers rather than type names. Specifically, “node_a” denotes a configuration component of type “Node_A”; “node_b”, “node_b1”, “node_b2”, and “node_b3” denote configuration components of type “Node_B”; “node_c”, “node_c1”, “node_c2”, and “node_c3” denote configuration components of type “Node_C”; and “node_d” denotes a configuration component of type “Node_D”. Similarly, “edge_a”, “edge_a1”, “edge_a2”, and “edge_a3” denote relationships of type “Edge_A”; “edge_b”, “edge_b1”, “edge_b2”, and “edge_b3” denote relationships of type “Edge_B”; “edge_c”, “edge_c1”, “edge_c2”, and “edge_c3” denote relationships of type “Edge_C”; and “one_of1”, “one_of2”, and “one_of3” denote relationships of type “One_Of”. In the figure, configuration elements with identifiers that differ only by their numerical suffix, such as “node_b1”, “node_b2”, and “node_b3”, are grouped and represented as “node_b1˜3”.

First, FIG. 14 is used to describe a specific example of the decomposition process where the number of expansion destination configuration elements is specified as an absolute value. The configuration shown in FIG. 14 (a) is based on the system configuration of FIG. 11 (c) and is an example of a system configuration in which the multi-element is expanded without being decomposed, and the number of expansion destination configuration elements is specified as an absolute value. However, for the configuration shown in FIG. 11 (c), the numbers of each configuration element are specifically set as n1=2, n2=3, n3=2, e1=1, and e2=1. The parentheses ( ) following a variable indicate the concrete value of the variable in this example. Additionally, “node_d” and “edge_c” have been added. While these configuration elements do not have an expansion dependency relationship with the decomposition-target element, they represent examples of configuration elements having a relationship with the decomposition-target element. These additions were made to describe a concrete example of the process described in [Step 5] of the decomposition of a multi-element in the present example embodiment. First, the multi-element to be decomposed is selected. In FIG. 14 (a), the decomposition process can be performed on any of the configuration elements “node_a”, “node_b”, and “node_c”, but “node_b” is selected from among them. Next, according to [Step 2], the selected “node_b” itself is decomposed. Specifically, three configuration elements of type “Node_B” with “quantity=1”, the same as the decomposition target, are generated (node_b1, node_b2, node_b3). Additionally, the decomposition-target element “node_b” is connected to the configuration elements (node_b1˜3) generated through the decomposition via the relationships “one_of1˜3” (FIG. 14 (b)). In the configuration shown in FIG. 14 (b), since the decomposition-target element “node_b” does not have any other configuration elements as expansion dependencies, the process in [Step 3] is not performed. Furthermore, since there are no configuration elements with direct and indirect expansion dependencies on the decomposition-target element “node_b”, the process in [Step 4] is skipped, and the process proceeds to [Step 5]. In accordance with [Step 5], the “edge_b”, which is a relationship with “node_b”, the decomposition origin in [Step 2], as the connection origin, is copied and connected to the decomposed “node_b1˜3” (FIG. 14 (c)). Finally, since there are no configuration elements that have “node_b” as a expansion dependency, the removal process in [Step 6] is skipped, and the decomposition of the multi-element is completed.

Next, FIG. 15 is used to describe a specific example of the decomposition process where the number of expansion destination configuration elements is specified as a relative value. The configuration shown in FIG. 15 (a) is based on the system configuration of FIG. 12 (c) and is an example of a system configuration in which the multi-element is expanded without being decomposed, and the number of expansion destination configuration elements is specified as an absolute value. For the configuration shown in FIG. 12 (c), the number of each configuration element is set to a concrete value, and “node_d” and “edge_c” are added, similar to FIG. 14.

First, the multi-element to be decomposed is selected. In FIG. 15 (a), “node_b” is selected ([Step 1]), similarly to FIG. 14 (a). Next, according to [Step 2], the selected “node_b” itself is decomposed. Specifically, three configuration elements of type “Node_B” with “quantity=1”, the same as the decomposition target, are generated (node_b1, node_b2, node_b3). Additionally, the decomposition-target element “node_b” is connected to the configuration elements (node_b1˜3) generated through the decomposition via the relationships “one_of1˜3” (FIG. 15 (b)). Since the decomposition-target element “node_b” has “node_a” as a expansion dependency, in accordance with [Step 3], the relationship “edge_a” between “node_b” and “node_a” is copied and connected to “node_b1˜3” (edge_a1˜3). At this time, “node_b1˜3” and “edge_a1˜3” also copy the information indicating their expansion dependency on “node_a”. Specifically, the “node_b1˜3” retain the information of their quantity as “1 on n1(2)”, representing their quantity per one “node_a” and the number of “node_a”. Similarly, “edge_a1˜3” retain “e1(1) on n1(2)” (FIG. 15 (c)). Next, in accordance with [Step 4], the partial configuration that has direct and indirect expansion dependencies on the decomposition-target element “node_b” are copied and connected to “node_b1˜3”. In FIG. 15, since “node_c” and “edge_b” have expansion dependencies on “node_b”, the partial configuration including “node_c” and “edge_b” are copied, retaining their quantity and expansion dependency information, and connected to “node_b1˜3” (FIG. 15 (d)). However, in the quantity of the configuration element of the expansion dependency destination retained by “node_c” and “edge_b”, the value representing the number of “node_b”, labeled as “n2”, is updated to “1” during the copying process. For example, the quantity information retained by “node_c1” is updated from “[n3(2) on n2(3) on n1(2)]” to “[n3(2) on 1 on n1(2)]”. Then, in accordance with [Step 5], the “edge_c” with “node_b” being the decomposition origin in [Step 2], as the connection destination, is copied and connected to the decomposed “node_b1˜3” (FIG. 15 (e)). Finally, in accordance with [Step 6], “node_c” and “edge_b”, which have direct and indirect expansion dependencies on the decomposition-target element “node_b”, are removed, and the decomposition process of the multi-element “node_b” is completed (FIG. 15 (f)). By applying the above process to “node_a” and “node_c” also, it is possible to design a configuration where all multi-elements are decomposed in the end.

### [Designing Various System Configurations Based on the Difference in Timing of Decomposing the Multi-Element]

In the technique according to the present example embodiment, when concretizing a multi-element, it is not limited to either decomposing the multi-element to advance the design, or expanding it and continuing the design while remaining as a multi-element, and either option may be selected. Furthermore, if the expansion proceeds while remaining as a multi-element, the timing for decomposing the multi-element can also be selected freely. Thus, by allowing the timing of the decomposition of the multi-element to be freely selected, various redundant configurations can be designed.

For example, in the case of designing a redundant configuration including multiple systems operating with different configurations, it is effective to prioritize the decomposition of multi-elements and advance the design. In the case of prioritizing the decomposition of multi-elements, the configuration elements generated through decomposition are subsequently concretized independently from that point onward. As a result, a system configuration in which each decomposed configuration element operates with a different configuration can be designed.

On the other hand, in the case of designing a redundant configuration including multiple systems operating with the same configuration, that is, multiple systems where the same software is installed on machines of the same type, it is effective to proceed with the expanding while keeping multi-elements grouped together. By prioritizing the expansion of multi-elements and subsequently decomposing them, the configuration completed as grouped multi-elements will also be copied in each of the configuration elements after decomposition, enabling the design of a redundant configuration including multiple redundant systems with a shared partial configuration.

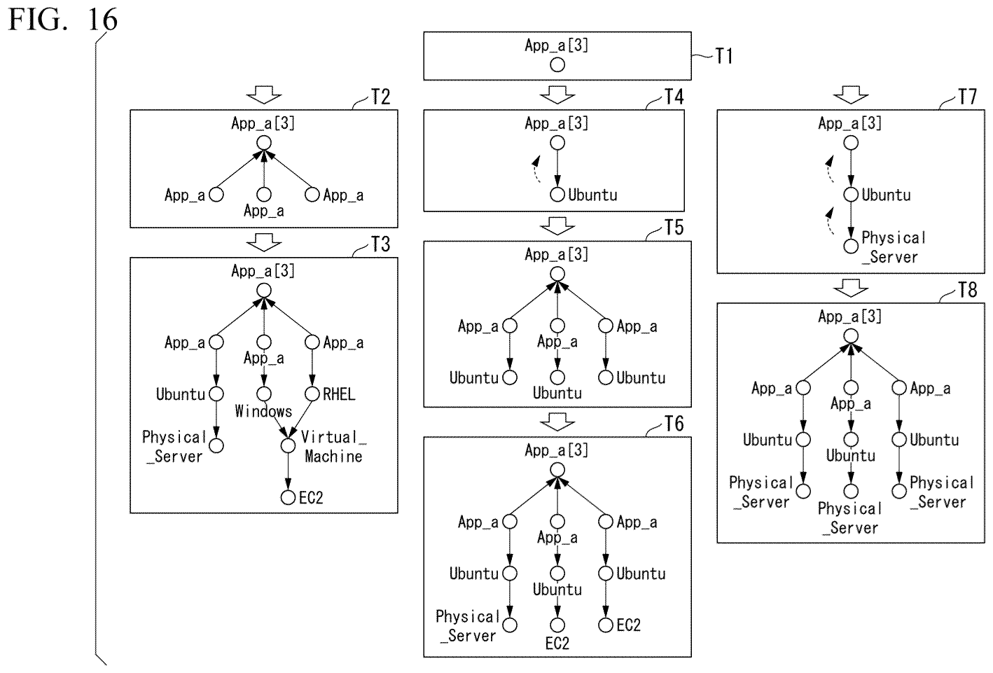

FIG. 16 shows an example of a system configuration designed according to the difference in the timing of the decomposition of multi-elements. With an abstract requirement of having three instances of application “a” (App_a) as input (T1), when prioritizing the decomposition of multi-elements, the requirement is first concretized into a configuration where three instances of “App_a”, each with “quantity=1”, are created (T2). Then, each of the three instances of “App_a” is independently concretized to generate the required configuration elements (T3). Specifically, when generating an OS that hosts “App_a”, the type of OS is arbitrarily selected from among Ubuntu (registered trademark), Windows (registered trademark), and RHEL (Red Hut Enterprise Linux) (registered trademark). Furthermore, a certain portion is concretized as a configuration where the OS is installed directly on a physical machine, while another portion is concretized as a configuration where the OSes are installed on virtual machines (Virtual_Machine) hosted on EC2 (Elastic Compute Cloud) instances within AWS (Amazon Web Services). Thus, by prioritizing the decomposition of multi-elements, it becomes possible to design a redundant configuration that contains a wide range of diverse configurations.

On the other hand, in the case where the expansion of multi-elements is prioritized, “App_a” is not decomposed, but is concretized by generating “Ubuntu” (registered trademark) as the OS, which is the expected surrounding configuration of “App_a”, and is further concretized by generating a “Physical_Server” as the “Machine”, which is the expected surrounding configuration of the OS (T7). Finally, as a decomposition of “App_a[3]”, the partial configuration including “Ubuntu” (registered trademark) and “Physical_Server” is copied and connected to the decomposed “App_a” (T8). By prioritizing the expansion of multi-elements in this manner, the configuration that is concretized prior to decomposition is copied and concretized into each configuration element after the decomposition, making it possible to efficiently design a redundant configuration with a shared partial configuration.

Furthermore, T1→T4→T5→T6 of FIG. 16 shows an example of the concretization flow when expansion is performed at an arbitrary timing, instead of always prioritizing either the decomposition or expansion of multi-elements. “App_a[3]” is not immediately decomposed, but is concretized by generating “Ubuntu” (registered trademark) while remaining as a multi-element (T4). At this point, “App_a[3]” is decomposed, and is concretized into three redundant configurations that share a partial configuration including “App_a” and “Ubuntu” (registered trademark) (T5). Subsequently, as each instance of “Ubuntu” (registered trademark) is concretized independently, configurations where the OS is installed on a physical server or configurations where installed on EC2, among other variations, are designed (T6).

The technique according to the present example embodiment enables the design of various types of redundant configurations by allowing flexibility in selecting the timing for multi-element decomposition. Also, in the case of designing a system configuration that includes a common partial configuration, this technique enables efficient design of the system by expanding the multi-element while remaining as a multi-element and then decomposing it, thereby shortening the automated system design time. However, it does not guarantee the design of any specific redundant configuration. Thus, in order to restrict the design to a specific redundant configuration, it is effective to combine this technique with a mechanism that restricts the target system configuration. For example, in order to design a configuration that uses a variety of software types while taking security into consideration, constraints can be integrated into the system configuration concretization process. Such constraints may discard configurations in which the same software is selected, and select configurations that prioritize decomposition of multi-elements. Conversely, in order to design a redundant configuration with a shared partial configuration for the purposes of cost or management, this can be achieved by incorporating constraints that reject configurations in which different software is selected. Moreover, integrating AI technology to infer the configuration to be selected based on the requirements expected by the designer can effectively prioritize the design of a configuration that aligns with the designer's expectations.

Furthermore, depending on the purpose of the designed system configuration, it can be effective to complete the design without decomposing the multi-element and keeping it as a multi-element. This is because presenting a multi-element in a combined state, without decomposing it into individual elements, allows for an easier understanding of the overall framework of the system configuration. As the number of configuration elements in the system grows, the configuration becomes more complex, making it harder to understand the overall framework, such as the types of configuration elements involved in the system and the connection relationships between them. Thus, displaying redundant portions that share the same configuration in a unified manner facilitates the understanding of the system's overall framework. For example, in the case of a redundant configuration including multiple systems with a shared partial configuration, as shown in T8 of FIG. 16, the design may be completed and output in the state shown in T7 of FIG. 16, before the multi-element is decomposed.

### [Description of Operation]

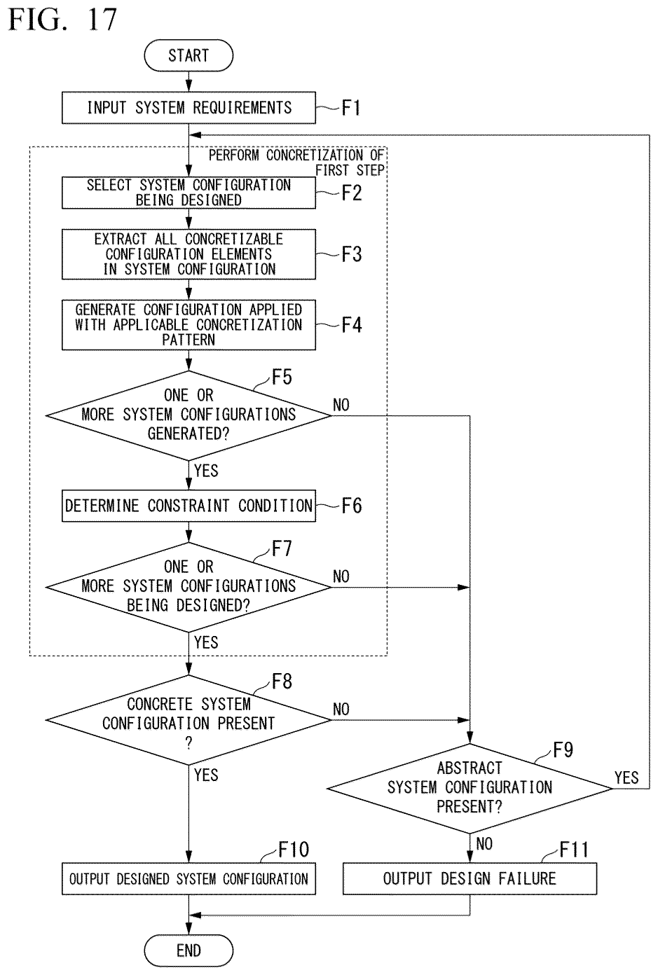

Next, the process flow for the automated system design of the present example embodiment will be described. FIG. 17 is a flowchart showing the overall operation of the automated system design device 10 in the present example embodiment. The user inputs system requirements (F1). The automated system design device 10 concretizes the system requirements in stages (F2 to F9), outputs a completely concretized system configuration or a design failure (F10, F11), and ends the automated system design process. In the process of concretizing the system configuration in stages, the configuration concretization unit 200 initially performs a one-stage concretization process (F2 to F7) and validates whether a concrete system configuration is included in the acquired multiple resultant configurations under designed (F8). A concrete system configuration refers to a system configuration in which there are no remaining abstract configuration elements, and all the expected surrounding configurations for each configuration element are satisfied. It signifies a system configuration where the design process is complete. If a concrete system configuration is included (Yes in F8), the input/output unit 100 outputs the concrete configuration (F10) and concludes the process. If a concrete system configuration is not included (No in F8), the configuration concretization unit 200 validates whether there are still any abstract system configurations remaining (F9). An abstract system configuration refers to one in which there are one or more abstract configuration elements or configuration elements that do not satisfy the expected surrounding configurations. It signifies a system configuration under design. If an abstract system configuration is included (Yes in F9), the process returns to the process of selecting the next system configuration to be concretized (F2) and performs the one-stage concretization process once more. If no abstract system configuration remains (No in F9), no further concretization can be performed, and the input/output unit 100 outputs a design failure (F11) and concludes the process.

During the one-stage concretization process, the configuration concretization unit 200 selects either system requirements acquired by the input/output unit 100 (F2) or a system configuration under design, and extracts all the concretizable configuration elements included in the selected configuration (F3). A concretizable configuration element refers to a configuration element that is either of an abstract type or one whose expected surrounding configuration is not yet satisfied. Thereafter, the design information application unit 210 of the configuration concretization unit 200 generates a system configuration by applying applicable concretization patterns to the configuration elements extracted in F3. There are two types of concretization patterns: a pattern of concretizing into a configuration that concretizes its own type; and a pattern of concretizing into a configuration that satisfies its expected surrounding configuration. Both are collectively referred to as concretization patterns. If there are multiple concretization patterns that can be applied to a single configuration element, a configuration is generated by applying each concretization pattern (F4). Subsequently, the configuration concretization unit 200 checks whether one or more system configurations have been generated (F5). If one or more system configurations have not been generated (No in F5), one-stage concretization for the system configuration selected in F2 has failed, so the configuration concretization unit 200 checks whether other abstract system configurations are present (F9). If one or more system configurations have been generated (Yes in F5), the configuration concretization unit 200 uses the validation unit 400 to validate the constraint conditions included in the system configurations, and rejects any system configuration that does not satisfy the constraint conditions (F6). Subsequently, the configuration concretization unit 200 checks whether there is one or more system configurations that have not been rejected (F7). If one or more system configurations are present (Yes in F7), the one-stage concretization is deemed successful, and it is checked whether a concrete system configuration is present (F8). If no system configuration remains (No in F7), one-step concretization has failed, so the process proceeds to check whether other abstract system configurations are present (F9).

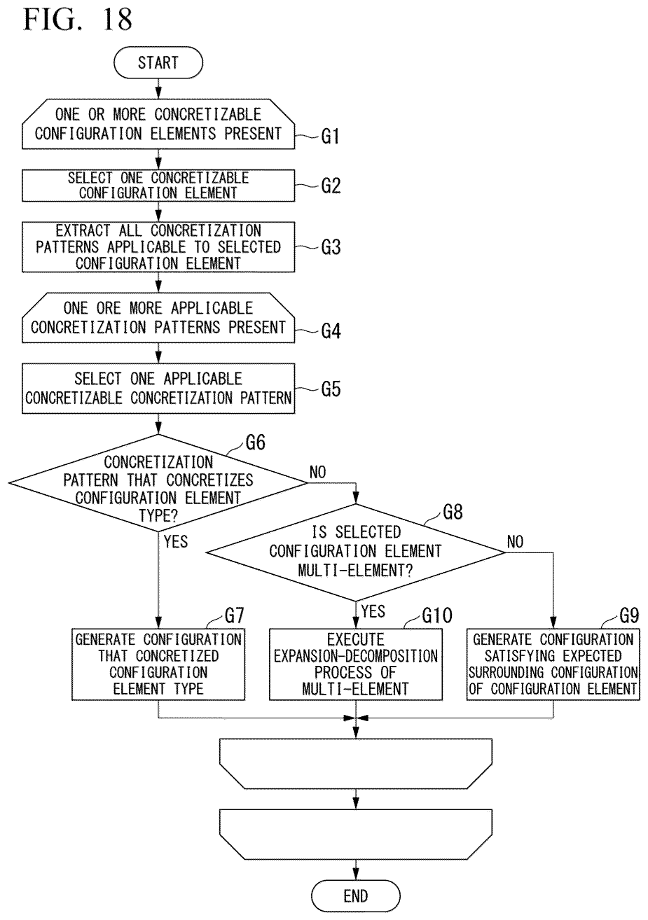

FIG. 18 is a detailed flowchart of the process executed in F4 of FIG. 17 for extracting all system configurations that can be generated through a one-stage concretization process for one abstract system configuration. The processes from G1 to G9 are executed by the design information application unit 210, while the process G10 is executed by the expansion dependency concretization unit 220. From the configuration elements extracted in F3 of FIG. 17, one concretization target configuration element is selected (G2), and all applicable concretization patterns for that configuration element are extracted (G3). Then, one of all the extracted concretization patterns is selected (G5). If the selected concretization pattern is a concretization pattern that concretizes the type of the configuration element itself (Yes in G6), a configuration plan that concretizes the type of that configuration element is generated (G7), and the process of generating one system configuration plan is concluded. If the concretization pattern does not concretize the type of the configuration element itself, that is, if the pattern concretizes into a configuration that satisfies the expected surrounding configuration of the configuration element (No in G6), it is checked whether the concretization target configuration element is a multi-element (G8). If it is not a multi-element (No in G8), the system configuration is concretized in such a way that it satisfies the expected surrounding configuration of the concretization target configuration element (G9), and the process of generating one system configuration proposal is concluded. If it is a multi-element (Yes in G8), the system configuration is concretized by executing the expansion and decomposition processes of the multi-element (G10), and the process of generating one system configuration plan is concluded. The processes described in G5 to G10 are executed for all concretization patterns extracted in G3 (G4), and the processes G2 to G10 are executed for all configuration elements extracted in F3 of FIG. 17 (G1), thereby completing the extraction process of system configurations that can be generated through the one-stage concretization process performed for one system configuration.

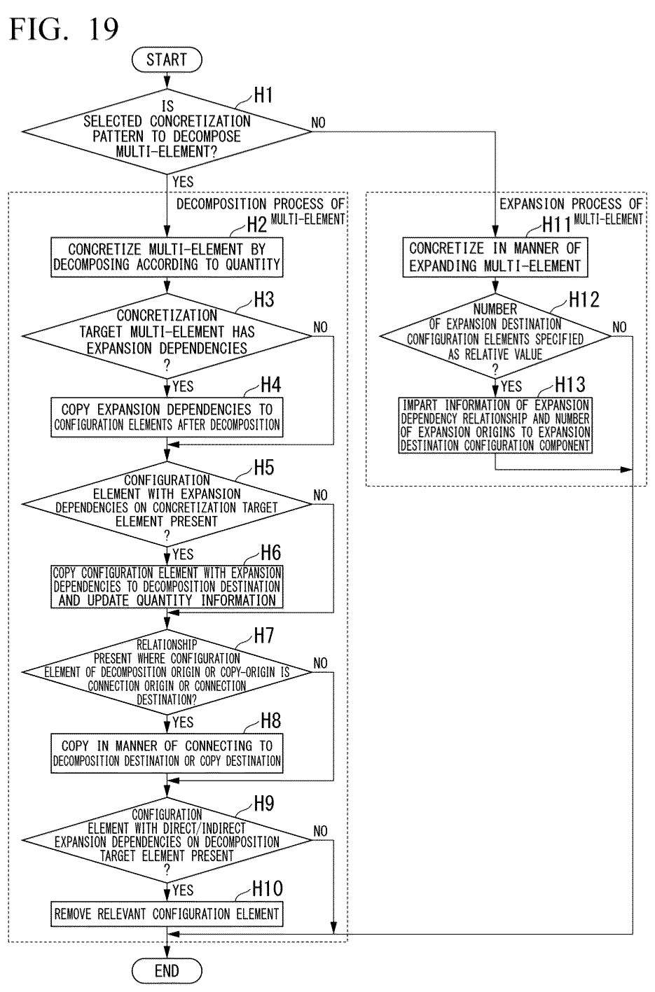

FIG. 19 is a flowchart showing the details of the expansion and decomposition processes of a multi-element executed in G10 of FIG. 18. The following processes are executed by the expansion dependency concretization unit 220. In the expansion and decomposition processes of a multi-element, first, it is checked whether the concretization pattern selected in G5 of FIG. 18 is a concretization pattern for decomposing a multi-element (H1). If it is not a concretization pattern for decomposing a multi-element (No in H1), the multi-element is expanded, that is, concretized into a configuration that satisfies the expected surrounding configuration of the multi-element in a way other than decomposition (H11). Then, it is checked whether the number of configuration elements generated through the expansion is specified by a relative value (H12). If the value is not a relative value, that is, if the value is specified as an absolute value (No in H12), the process ends. If the value is a relative value (Yes in H12), the configuration component generated through the expansion in H11 is imparted with information of the expansion dependency relationship with the concretization target multi-element and the number of the expansion-origin configuration elements (H13), and the process ends. If it is a concretization pattern that decomposes a multi-element (Yes in H1), the multi-element itself is decomposed, that is to say, the concretization target configuration elements are generated in the number of the quantity (H2). Thereafter, it is checked whether the concretization target element has any expansion dependencies (H3). If the element has an expansion dependency (Yes in H3), the expansion dependency is copied for the configuration element created through decomposition (H4). After the process shown in H4 is executed, or if the element has no expansion dependency (No in H3), it is checked whether there is any configuration element in the system configuration that has direct and indirect expansion dependencies on the concretization target element (H5). If there is such an element, the partial configuration including the configuration elements having expansion dependencies is copied in a manner of connecting to the decomposition-destination configuration element of the concretization target element, and the information on the number of concretization target elements retained by the configuration elements having expansion dependencies is updated to “1” (H6). After the process shown in H6 is executed, or if there are no the configuration elements having expansion dependencies (No in H5), it is then checked whether there is a relationship in which the decomposition-origin configuration element in the process H2 or the copy-origin configuration element in the process H6 is a connection origin or connection destination (H7). If such a relationship exists, the relationship is copied in a manner of connecting to each decomposition-destination configuration element or copy-destination configuration element (H8). After the process shown in H8 is executed, or if the above relationship does not exist, it is finally checked whether there is a configuration element that has a direct or indirect expansion dependency on the decomposition-target element (H9). If such a configuration element exists (Yes in H9), the configuration element is removed (H10) and the process ends. If such a configuration element does not exist (No in H9), the process ends.

### (Effects)

As described above, when concretizing a multi-element representing the existence of multiple configuration elements, it is possible to advance concretizing the system configuration while remaining as a multi-element, and this enables efficient and automated design of redundant configurations having a shared partial configuration.

### Second Example Embodiment

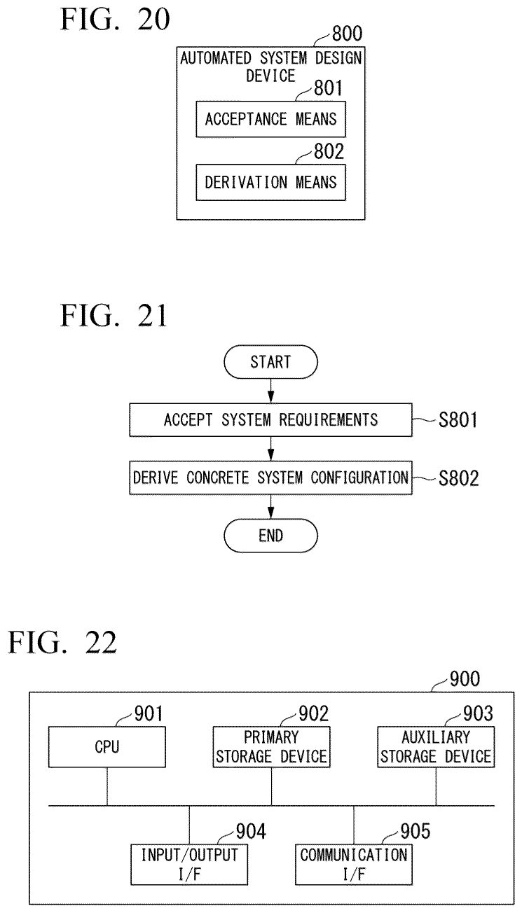

FIG. 20 is a second diagram showing an example of an automated system design device according to an example embodiment. An automated system design device 800 includes: an acceptance means 801 for accepting system requirements; and a derivation means 802 for deriving a concrete system configuration by applying a predefined concretization pattern for each configuration element based on the system requirements. The derivation means 802 has a function to design a redundant configuration from a multi-element including an unspecified number of, or two or more of the configuration elements in a case where the multi-element is a single configuration element that represents a plurality of configuration elements of a same type, and when concretizing the multi-element, advances the concretization of the multi-element without decomposing it into individual configuration elements to thereby design a redundant system configuration.

FIG. 21 is a second flowchart showing an example of an operation of the automated system design device. The acceptance means 801 accepts system requirements, and the derivation means 802 derives a concrete system configuration by applying a predefined concretization pattern for each configuration element based on the system requirements. In a case where the multi-element is a single configuration element that represents a plurality of configuration elements of a same type, then when concretizing the multi-element, the concretization of the multi-element is advanced without decomposing it into individual configuration elements to thereby design a redundant system configuration.

FIG. 22 is a block diagram showing a hardware configuration example of an automated system design device according to the example embodiments. A computer 900 includes a CPU 901, a primary storage device 902, an auxiliary storage device 903, an input/output interface 904, and a communication interface 905. The automated system design device 10 described above is implemented in the computer 900. Each of the functions described above is stored in the auxiliary storage device 903 in the form of a program. The CPU 901 reads the program from the auxiliary memory storage device 903, loads it on the main memory storage device 902, and executes the processing described above according to the program. Moreover, the CPU 901 secures a memory storage region in the main memory storage device 902 according to the program. Also, the CPU 901 secures a memory storage region in the auxiliary memory storage device 903 according to the program.

It can be noted that a program for implementing some or all of the processes performed by the automated system design device 10 may be recorded on a computer-readable recording medium, and the program recorded on the recording medium may be read into and executed on a computer system, to thereby perform the processing of each functional unit. The “computer system” referred to here, includes an operating system and hardware such as peripheral devices. Moreover, the “computer system” also includes the homepage provision environment (or display environment) if a WWW system is used. Moreover, the “computer-readable recording medium” here refers to a portable medium such as a CD, DVD, and USB memory, or a storage device such as a hard disk built into a computer system. Furthermore, when this program is distributed to the computer 900 via a communication line, the computer 900 which has received the distribution may load the program on the main memory storage device 902 and may execute the above processing. The above program may be a program for implementing some of the functions described above, and may be a program capable of implementing the functions described above in combination with a program already recorded in a computer system.

The example embodiments of the present disclosure have been described in detail with reference to the drawings. However, the specific configuration of the invention is not limited to the example embodiments described above, and various design changes may be made thereto without departing from the scope of the present invention. Moreover, one aspect of the present disclosure allows various modifications within the scope of the claims, and example embodiments obtained by suitably combining the disclosed technical means from different example embodiments are also encompassed within the technical scope of the present disclosure. Furthermore, elements disclosed in each of the above example embodiments and modified examples, including configurations where elements with similar effects are replaced, are also encompassed. Moreover, each of the example embodiments may be combined with another example embodiment where appropriate.

As mentioned above, the automated system design technique is disclosed. A technique is required to efficiently, that is, in a short time, automatically design redundant system configurations.

According to the present disclosure, for example, in automated system design, by advancing the design while keeping together the configuration elements that are concretized in the same partial configuration (referring to the partial configuration within the system as a whole), the amount of processing required to complete system design can be reduced, and a concrete system configuration can be automatically designed in a short period of time.

A part or all of the example embodiments described above can be written as in the supplementary notes below, but is not limited thereto.

### (Supplementary Note 1)

An automated system design device comprising:
a means for accepting a system requirement; and
a means for deriving a concrete system configuration by applying a predefined concretization pattern for each configuration element based on the system requirement, wherein
the means for deriving a system configuration has a function to design a redundant configuration from a multi-element including an unspecified number of, or two or more of the configuration elements in a case where the multi-element is a single configuration element that represents a plurality of configuration elements of a same type, and in concretizing the multi-element, advances the concretization of the multi-element without decomposing it into individual configuration elements to thereby design a redundant system configuration.

### (Supplementary Note 2)

The automated system design device according to supplementary note 1, wherein
the means for deriving a system configuration:
further has a function to decompose the multi-element into individual configuration elements and concretize them; and
in concretizing the multi-element, in a case of concretizing the multi-element without decomposing it, advances the concretization while retaining information that the multi-element has been concretized, and in a case of concretizing the multi-element by decomposing it, decomposes and concretizes the multi-element including surrounding configuration elements required for the multi-element to exist.

### (Supplementary Note 3)

The automated system design device according to supplementary note 1 or 2, wherein
in advancing the concretization of the multi-element without decomposing it, a configuration element generated by the concretization retains, as information indicating that the multi-element has been concretized, information on a relationship indicating from which multi-element an expansion originated and a value of a number of the multi-element targeted for concretization.

### (Supplementary Note 4)

The automated system design device according to any one of supplementary notes 1 to 3, wherein
a process of advancing the concretization by decomposing the multi-element, includes a first process of decomposing the multi-element itself, a second process of decomposing a partial configuration related to the multi-element, and a process of removing the configuration elements rendered unnecessary by the first process and the second process.

### (Supplementary Note 5)

The automated system design device according to supplementary note 4, wherein
the first process of decomposing the multi-element itself includes a decomposition process that generates a plurality of configuration elements of the same type as the multi-element itself, and further includes a process of, in a case where the multi-element targeted for decomposition retains information indicating that another of the multi-element has been concretized, imparting the information to a plurality of the configuration elements generated through the decomposition process.

### (Supplementary Note 6)

The automated system design device according to supplementary notes 4 to 5, wherein
the means for deriving a system configuration extracts a configuration that includes, as the partial configuration related to the multi-element, configuration elements directly required by the multi-element and elements indirectly required by the multi-element.

### (Supplementary Note 7)

The automated system design device according to supplementary notes 1 to 6, wherein
the means for deriving a system configuration, in concretizing a multi-element, by being able to select whether to advance designing by decomposing the multi-element or to advance designing without decomposing the multi-element, designs a system configuration having a different redundant configuration according to a time of decomposing the multi-element.

### (Supplementary Note 8)

An automated system design method comprising:
accepting a system requirement; and
deriving a concrete system configuration by applying a predefined concretization pattern for each configuration element based on the system requirement, wherein
in the deriving, in a case where the multi-element is a single configuration element that represents a plurality of configuration elements of a same type, the concretization of the multi-element is advanced without decomposing it into individual configuration elements to derive the redundant configuration from the multi-element including an unspecified number of, or two or more of the configuration elements.

### (Supplementary Note 9)

A program that causes a computer to execute steps of:
accepting a system requirement; and
deriving a concrete system configuration by applying a predefined concretization pattern for each configuration element based on the system requirement, wherein
in the deriving, in a case where the multi-element is a single configuration element that represents a plurality of configuration elements of a same type, the concretization of the multi-element is advanced without decomposing it into individual configuration elements to derive the redundant configuration from the multi-element including an unspecified number of, or two or more of the configuration elements.

While preferred embodiments of the invention have been described and illustrated above, it will be understood that these are exemplary of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

What is claimed is:

1. An automated system design device comprising
at least one memory configured to store instructions; and
at least one processor configured to execute the instructions to:
accept a system requirement; and
derive a concrete system configuration by applying a predefined concretization pattern for each configuration element based on the system requirement,
wherein the at least one processor is configured to execute the instructions to:
design a redundant configuration from a multi-element including an unspecified number of, or two or more of the configuration elements in a case where the multi-element is a single configuration element that represents a plurality of configuration elements of a same type, and
in concretizing the multi-element, advance the concretization of the multi-element without decomposing it into individual configuration elements to thereby design a redundant system configuration.

2. The automated system design device according to claim 1,
wherein the at least one processor is configured to execute the instructions to:
decompose the multi-element into individual configuration elements and concretize them; and
in concretizing the multi-element, in a case of concretizing the multi-element without decomposing it, advance the concretization while retaining information that the multi-element has been concretized, and in a case of concretizing the multi-element by decomposing it, decompose and concretizes the multi-element including surrounding configuration elements required for the multi-element to exist.

3. The automated system design device according to claim 1, wherein
in advancing the concretization of the multi-element without decomposing it, a configuration element generated by the concretization retains, as information indicating that the multi-element has been concretized, information on a relationship indicating from which multi-element an expansion originated and a value of a number of the multi-element targeted for concretization.

4. The automated system design device according to claim 2, wherein
a process of advancing the concretization by decomposing the multi-element, includes a first process of decomposing the multi-element itself, a second process of decomposing a partial configuration related to the multi-element, and a process of removing the configuration elements rendered unnecessary by the first process and the second process.

5. The automated system design device according to claim 4, wherein
the first process of decomposing the multi-element itself includes a decomposition process that generates a plurality of configuration elements of the same type as the multi-element itself, and further includes a process of, in a case where the multi-element targeted for decomposition retains information indicating that another of the multi-element has been concretized, imparting the information to a plurality of the configuration elements generated through the decomposition process.

6. The automated system design device according to claim 4,
wherein the at least one processor is configured to execute the instructions to:
extract a configuration that includes, as the partial configuration related to the multi-element, configuration elements directly required by the multi-element and elements indirectly required by the multi-element.

7. The automated system design device according to claim 1,
wherein the at least one processor is configured to execute the instructions to:
in concretizing a multi-element, design, by being able to select whether to advance designing by decomposing the multi-element or to advance designing without decomposing the multi-element, a system configuration having a different redundant configuration according to a time of decomposing the multi-element.

8. An automated system design method comprising:
accepting a system requirement; and
deriving a concrete system configuration by applying a predefined concretization pattern for each configuration element based on the system requirement,
wherein
in the deriving, in a case where the multi-element is a single configuration element that represents a plurality of configuration elements of a same type, the concretization of the multi-element is advanced without decomposing it into individual configuration elements to derive the redundant configuration from the multi-element including an unspecified number of, or two or more of the configuration elements.

9. A non-transitory storage medium that stores a program that causes a computer to execute processes, the processes comprising:
accepting a system requirement; and
deriving a concrete system configuration by applying a predefined concretization pattern for each configuration element based on the system requirement,
wherein
in the deriving, in a case where the multi-element is a single configuration element that represents a plurality of configuration elements of a same type, the concretization of the multi-element is advanced without decomposing it into individual configuration elements to derive the redundant configuration from the multi-element including an unspecified number of, or two or more of the configuration elements.
